(19) United States
(12) Patent Application Publication
(10) Pub. No.: US 2005/0001275 A1
(43) Pub. Date: Jan. 6, 2005

(54) Semiconductor dynamic quantity sensor

(75) Inventors: Makiko Sugiura, Hekinan-city (JP); Kazuhiko Kano, Toyoake-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/849,259

(22) Filed: May 20, 2004

(30) Foreign Application Priority Data
May 23, 2003 (JP) 2003-145877

(51) Int. Cl. H01L 27/14

(52) U.S. Cl. 257/414

(57) ABSTRACT

An acceleration sensor comprising a spring portion joined to the base portion of a semiconductor substrate and elastically displaced in Y-direction in accordance with an applied acceleration, movable electrodes joined to the spring portion, fixed electrodes disposed to face the movable electrodes and adjusting electrodes for adjusting the spring constant of the spring portion. The spring portion has a pair of beams facing each other in the Y-direction, and is elastically deformed so that the interval between the pair of beams is varied. The adjusting electrodes are respectively equipped at the outside of one of the paired beams and at the outside of the other beam, and electrostatic force can be applied by the adjusting electrodes so that the paired beams are separated from each other.

### CROSS REFERENCE TO RELATED APPLICATION

This application is based upon, claims the benefit of priority of, and incorporates by reference the contents of Japanese Patent Application No. 2003-145877 filed on May 23, 2003.

### FIELD OF THE INVENTION

The present invention relates generally to a dynamic quantity sensor and, more particularly, to a dynamic quantity sensor including an adjusting electrode for adjusting a spring constant of a spring portion.

### BACKGROUND OF THE INVENTION

A conventional dynamic quantity sensor, or, more specifically, a capacitance type dynamic quantity sensor includes a base portion, a spring portion which is joined to the base portion and is elastically displaced in a predetermined direction in accordance with an applied dynamic quantity, a movable electrode which is joined to the spring portion and displaceable in the predetermined direction together with the spring portion, and fixed electrodes which are fixed to the base portion and disposed so as to face the movable electrode. The base portion, the spring portion, the movable electrode and the fixed electrode of this dynamic quantity sensor are formed on a semiconductor substrate. When the movable electrode is displaced in the predetermined direction in accordance with the applied dynamic quantity, the applied dynamic quantity concerned is detected on the basis of variation of the interval between the movable electrode and the fixed electrode.

In order to prevent reduction in detection precision due to processing dispersion of the spring portion and thus enhance the detection precision, a dynamic quantity sensor having an adjusting electrode for adjusting the spring constant of the spring portion has been proposed as one of the above type dynamic quantity sensors in JP-A-2000-180180. According to this dynamic quantity sensor, electrostatic force is generated by applying a voltage to an adjusting electrode so that the spring constant of the spring portion (beam portion) is made variable.

Furthermore, a dynamic quantity sensor in which a spring portion has a fold-back (meandering) beam shape and each of a movable electrode and a fixed electrode is designed in a comb-shape has been also proposed as one of the above type dynamic quantity sensors in JP-A-11-326365.

FIG. 11 is a plan view of a general construction of such a dynamic quantity sensor as described above. The dynamic quantity sensor is formed by conducting trench etching on a semiconductor substrate 10 from one surface side thereof to form grooves, thereby forming a movable portion comprising spring portions 22 and movable electrodes 24 integrally formed with the spring portions 22, and fixed electrodes 32, 42 disposed so as to confront the movable electrodes 24.

The spring portions 22 have a spring function sufficient for being displaced in a direction of an arrow Y of FIG. 11 in accordance with an applied dynamic quantity, and have a beam shape extending in a direction perpendicular to the displacement direction Y. The plural movable electrodes 24 are formed integrally with the spring portions 22 so as to be disposed in a comb-shape arrangement along the displacement direction Y of the spring portion 22 and displaceable in the displacement direction Y together with the spring portion 22.

The plural fixed electrodes 32, 42 are fixedly mounted on the substrate 10 and disposed in a comb-shape arrangement so that the comb-shape of the fixed electrodes 32, 42 and the comb-shape of the movable electrodes 24 are engaged with each other, and the side surfaces of the fixed electrodes 32, 42 and the side surfaces of the movable electrodes 24 are confronted to one another.

CS1 represents the capacitance formed in the gap (electrode gap) between the movable electrode 24 and the fixed electrode 32 at the left side of FIG. 11, and CS2 represents the capacitance formed in the gap (electrode gap) between the movable electrode 24 and the fixed electrode 42 at the left side of FIG. 11. In this sensor, the capacitance CS1, CS2 between the movable electrode 24 and the fixed electrode 32, 42 at the right and left sides is varied in accordance with an applied dynamic quantity such as acceleration, angular velocity or the like. A signal based on the capacitance difference (CS1-CS2) between the capacitance CS1 and the capacitance CS2 thus varying is output as an output signal from the sensor. The signal thus output is processed in a circuit chip or the like (not shown) and finally output, thereby detecting the dynamic quantity.

In the dynamic quantity sensor shown in FIG. 11, each of the spring portions 22 has a pair of confronting portions facing each other along the predetermined direction Y. That is, in each of the spring portions 22 shown in FIG. 11, two beams 22a and 22b confront each other, and they are elastically deformed so that the interval between the confronting beams 22a and 22b is varied. Therefore, a phenomenon may occur in which the confronting beams 22a and 22b adhere to each other by electrostatic force or the like and thus they are not separated from each other, that is, sticking may occur. Furthermore, sticking may also occur between each movable electrode 24 and each fixed electrode 32, 42 which confront each other.

### SUMMARY OF THE INVENTION

Therefore, the present invention has been implemented in view of the foregoing problem, and has an object to provide a capacitance type dynamic quantity sensor having an adjusting electrode for compatibly adjusting the spring constant of a spring portion by the adjusting electrode and preventing sticking.

In order to attain the above object, according to a first aspect of the present invention, a dynamic quantity sensor having a base portion, a spring portion joined to the base portion and elastically displaceable in a predetermined direction (Y) in accordance with an applied dynamic quantity, a movable electrode joined to the spring portion and displaceable in the predetermined direction together with the spring portion, a fixed electrode fixed to the base portion and disposed so as to face the movable electrode, and adjusting electrodes for adjusting the spring constant of the spring portion, the applied dynamic quantity being detected on the basis of variation of the interval between the movable electrode and the fixed electrodes when the movable electrode is displaced in the predetermined direction in accordance with the applied dynamic quantity, is characterized in that the spring portion has a pair of confronting portions which face each other along the predetermined direction and are elastically deformed so that the interval between the confronting portions is varied, and the adjusting electrodes are equipped at such positions that sticking between the pair of confronting portions of the spring portion or sticking between the movable electrode and the fixed electrodes can be prevented.

According to the dynamic quantity sensor of the first aspect, the adjusting electrodes are strategically disposed at positions sufficient for preventing the sticking between the pair of confronting portions of the spring portion or the sticking between the movable electrode and the fixed electrode.

Accordingly, in the capacitance type dynamic quantity sensor having the adjusting electrodes, both of the adjustment of the spring constant of the spring portion by the adjusting electrodes and the prevention of the sticking can be performed.

According to a second aspect of the present invention, in the dynamic quantity sensor described above, the adjusting electrodes are respectively equipped at the outside of one of the pair of confronting portions and at the outside of the other confronting portion as the positions at which the sticking between the pair of confronting portions can be prevented, so that electrostatic force for separating the pair of confronting portions from each other can be applied by the adjusting electrodes.

According to the dynamic quantity sensor of the second aspect, the motion of the spring portion can be adjusted by applying a voltage to the adjusting electrodes so that the confronting portions of the spring portion are separated from each other.

Furthermore, even when the confronting portions of the spring portion come into contact with each other, the confronting portions can be separated from each other by the electrostatic force of the adjusting electrodes, so that the sticking in the spring portion can be properly prevented.

As described above, according to the capacitance type dynamic quantity sensor having the adjusting electrodes of the present invention, both of the adjustment of the spring constant of the spring portion by the adjusting electrodes and the prevention of the sticking can be performed compatibly.

According to a third aspect of the present invention, in the dynamic quantity sensor described above, the adjusting electrodes are interposed between the pair of confronting portions as the positions at which the sticking between the pair of confronting portions can be prevented.

According to the dynamic quantity sensor described above, electrostatic force can be generated by applying a voltage to the adjusting electrodes so that the adjusting electrodes and the spring portion attract each other or repel each other. Therefore, the spring constant of the spring portion can be adjusted.

Furthermore, since the adjusting electrodes are interposed between the confronting portions of the spring portion, there originally occurs no contact between the confronting portions, and thus the sticking in the spring portion can be prevented.

As described above, according to the capacitance type dynamic quantity sensor having the adjusting electrodes of the present invention, both the adjustment of the spring constant of the spring portion by the adjusting electrodes and the prevention of the sticking can be properly performed compatibly.

According to a fourth aspect of the present invention, in the dynamic quantity sensor described above, the adjusting electrodes are equipped in the neighborhood of the movable electrode at the positions at which the sticking between the movable electrode and the fixed electrode can be prevented, and the electrostatic force can be applied to the movable electrode by the adjusting electrodes so that the movable electrode and the fixed electrodes are separated from each other.

According to the dynamic quantity sensor of the fourth aspect, electrostatic force is generated by applying a voltage to the adjusting electrodes so that the movable electrode and the fixed electrode are separated from each other, and consequently the motion of the spring portion can be adjusted.

Even when the movable electrode and the fixed electrode come into contact with each other, both the electrodes can be separated from each other by the electrostatic force of the adjusting electrodes, so that the sticking between the movable electrode and the fixed electrode can be properly prevented.

As described above, according to the capacitance type dynamic quantity sensor having the adjusting electrodes of the present invention, both of the adjustment of the spring constant of the spring portion by the adjusting electrodes and the prevention of the sticking can be properly performed compatibly.

According to a fifth aspect of the present invention, in the dynamic quantity sensor described above, the movable electrode is designed in a comb-shape whose teeth extend in a direction perpendicular to the predetermined direction, and the fixed electrode is designed in a comb-shape and disposed so as to face the movable electrode so that each of the teeth of the comb-shape of the fixed electrode is fitted in the gap between the respective teeth of the comb-shape of the movable electrode (i.e., the comb-shaped portion of the fixed electrode is engaged with the comb-shaped portion of the movable electrode). Each of the adjusting electrodes is disposed so as to be fitted in the gap between the respective teeth of the comb-shaped portion of the movable electrode, and disposed at the opposite side of the movable electrode to the fixed electrode so as to face the movable electrode.

The dynamic quantity sensor of the fifth aspect of the present invention may be applied as the semiconductor dynamic quantity sensor of the fourth aspect.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic plan view showing an acceleration sensor according to a first preferred embodiment;

FIG. 2 is a schematic cross-sectional view taken along line 11-11 of FIG. 1;

FIG. 3 is a circuit diagram of a detection circuit for the acceleration sensor;

FIG. 4 is a schematic plan view showing an acceleration sensor according to a modification to the first preferred embodiment;

FIG. 5 is a schematic cross-sectional view taken along line V-V of FIG. 4;

FIG. 6 is a schematic plan view showing an acceleration sensor according to a second preferred embodiment;

FIG. 7 is a schematic cross-sectional view taken along line VII-VII of FIG. 6;

FIG. 8 is a schematic plan view of an acceleration sensor according to a modification to the second preferred embodiment;

FIG. 9 is a schematic plan view showing an acceleration sensor according to a third preferred embodiment;

FIG. 10 is a schematic cross-sectional view taken along line X-X of FIG. 9; and

FIG. 11 is a schematic plan view of a conventional acceleration sensor.

### DETAILED DESCRIPTION OF THE PREFERRED EMBODIMENTS

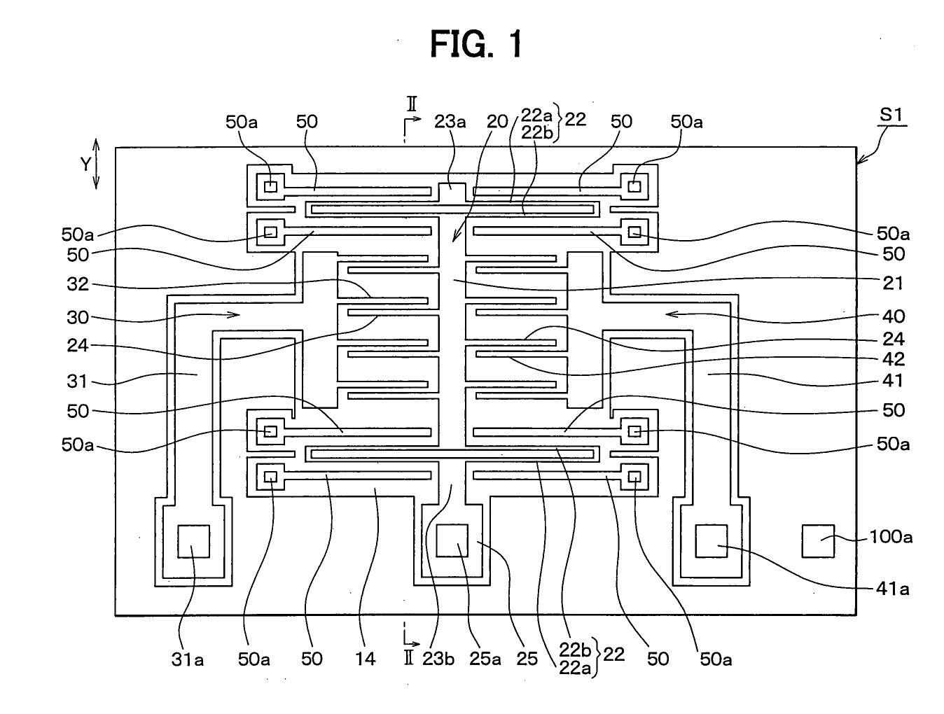

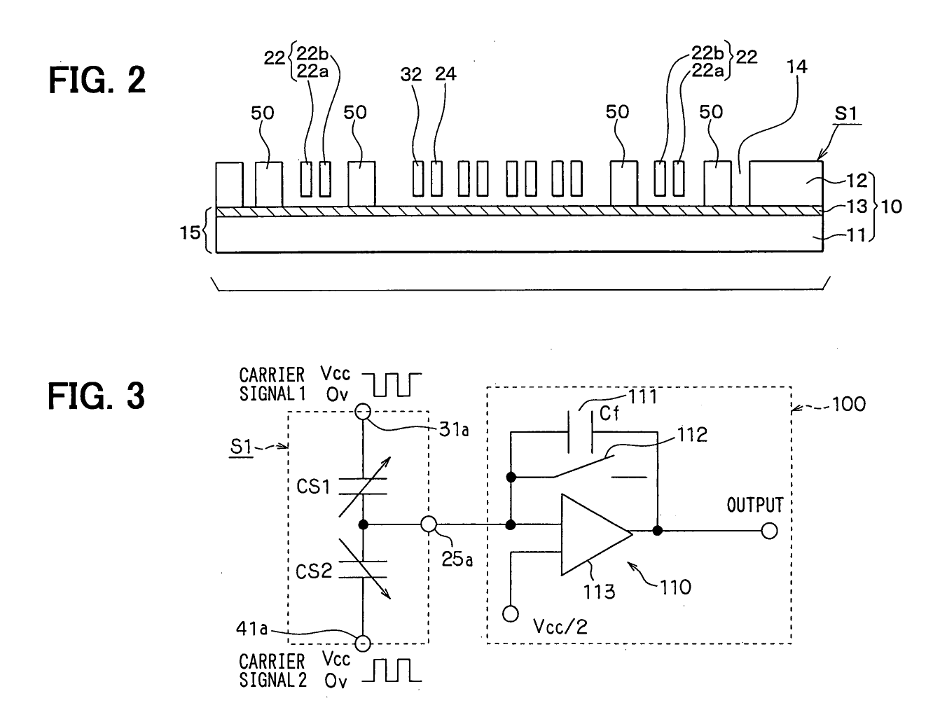

Referring to FIGS. 1-2, a first preferred embodiment of a differential capacitance type acceleration sensor S1 as a semiconductor dynamic quantity sensor will be discussed. The acceleration sensor S1 may be implemented as a vehicle acceleration sensor for controlling the actuation of an air bag, ABS, VSC, etc., a gyro sensor or the like.

Referring first to FIG. 2, a semiconductor substrate constituting the acceleration sensor S1 is a rectangular SOI substrate 10 having oxide film 13 as an insulating layer between a first silicon substrate 11 and a second silicon substrate 12. The first silicon substrate 11 and the oxide film 13 of the SOI substrate 10 are constructed as a base portion 15. The sensor is formed by well-known micro-fabrication techniques.

Grooves 14 are formed on the second silicon substrate 12 to form beam structures 20, 30, 40, 50. In this embodiment, these beam structures 20 to 50 are designed in a comb-shape, and comprise a movable portion 20 movable relative to the base portion 15, fixed portions 30, 40 fixed to the base portion 15 and adjusting electrodes 50.

The second silicon substrate 12 constituting the movable portion 20 and the comb-shaped portions of the fixed portions 30, 40 at the oxide film (13) side is removed, and thus these portions are kept floated above the oxide film 13.

The acceleration sensor S1 as described above is manufactured as follows. A mask having the shape corresponding to the beam structures is formed on the second silicon substrate 12 of the SOI substrate 10 by using the photolithography technique, and then trench etching is conducted by dry etching using gas of CF₄, SF₆ or the like to form grooves 14, whereby the beam structures 20 to 50 are formed in a lump. In the trench etching process, parts of the fixed portions 30, 40 and the adjusting electrodes 50 are set to be larger in width than those portions which are kept floated from the oxide film 13.

Accordingly, the lower portion of the second silicon substrate 12 is removed at the floated portions concerned by side etching, and the lower portion of the second silicon substrate 12 remains at the portions other than the floated portions concerned. Therefore, the second silicon substrate 12 is designed to have portions floated from the oxide film 12 and portions mounted on the oxide film 13, so that the beam structures 20 to 50 sectioned by the grooves 14 are formed.

Referring now to FIG. 1, the movable portion 20 is disposed so as to traverse the center portion of the semiconductor substrate 10, and it is designed so that both the ends of a poise 21 thereof are integrally joined to anchor portions 23a and 23b through spring portions 22. Here, the anchor portions 23a, 23b correspond to the portions mounted on the oxide film 13.

Each of the spring portions 22 is designed to have such a rectangular shape that two parallel beams 22a, 22b are joined to each other at both the ends thereof and to have such a spring function that it is elastically displaced in a direction perpendicular to the longitudinal direction of the two beams 22a, 22b. Specifically, the spring portions 22 are designed so as to displace the poise 21 in the direction of an arrow Y of FIG. 1 when an acceleration containing an acceleration component in the direction of the arrow Y, and also return the poise 21 to the original state in accordance with vanishing of the acceleration. In other words, each of the spring portions 22 has the two beams 22a and 22b as a pair of confronting portions facing each other in the direction of the arrow Y, and is elastically deformed so that the interval between the two beams 22a, 22b is increased/reduced.

Accordingly, the movable portion 20 is displaceable in the displacement direction of the spring portion 22, that is, in the direction of the arrow Y in accordance with the applied acceleration. The direction of the Y arrow will be hereinafter referred to as the displacement direction Y.

The movable portion 20 is equipped with a plurality of beam-shaped movable electrodes 24 extending from both the side surfaces of the poise 21 in the opposite directions along the direction perpendicular to the displacement direction Y In FIG. 1, four movable electrodes 24 are formed at each of the right and left sides of the poise 21 so as to project in the rightward and leftward directions, respectively. Each movable electrode 24 is designed in a beam shape having a rectangular section.

As described above, each movable electrode 24 is integrally formed with the spring portions 22 and the poise portion 21 to be joined to the spring portions 22 through the poise portion 21. The movable electrodes 24 are displaceable in the displacement direction Y together with the spring portion 22 and the poise portion 21.

The fixed portions 30, 40 are equipped at both the sides of the poise portion 21 so that the poise portion 21 is sandwiched between the fixed portions 30, 40, and comprise a first fixed portion 30 located at the left side of FIG. 1 and a second fixed portion 40 located at the right side of FIG. 1. These fixed portions 30, 40 are electrically independent of each other.

Each fixed portion 30, 40 comprises a wire portion 31, 41 which is fixed to the oxide film 13 and supported by the first silicon substrate 11, and plural (four in FIGS. 1, 2) fixed electrodes 32, 42 which are disposed so as to face the side surfaces of the movable electrodes 24 in parallel at predetermined detection intervals.

Here, the fixed electrodes 32 at the first fixed portion 30 side will be referred to as first fixed electrodes 32, and the fixed electrodes 42 at the second fixed portion 40 side will be referred to as second fixed electrodes 42. Each of the fixed electrodes 32 and 42 is designed in a beam shape to be rectangular in section and extend substantially in parallel to the movable electrodes 24, and cantilevered by each of the wire portions 31, 41 so as to be floated from the oxide film 13.

As described above, according to this embodiment, the movable electrodes 24 are formed in a comb-shape extending along the direction perpendicular to the displacement direction Y, and the fixed electrodes 32, 42 are designed in such a comb-shape that they face the movable electrodes 24 and are fitted in the gaps between the respective teeth of the comb shape of the movable electrodes 24.

Furthermore, fixed electrode pads 31a, 41a for wire bonding are formed at predetermined positions on the wire portions 31, 41 of the respective fixed portions 30, 40. Furthermore, a wire portion 25 for the movable electrodes is formed while integrally joined to the anchor portion 23b, and a wire bonding movable electrode pad 25a is formed at a predetermined position on the wire portion 25. Each of the electrode pads 25a, 31a, 41a is formed of aluminum or the like.

In order to apply potential to the second semiconductor substrate 12 at the portions other than the beam structures 20 to 50, an electrode pad 100a is formed. Like the above electrode pads, the electrode pad 100a is formed of aluminum or the like.

Furthermore, the acceleration sensor S1 of this embodiment is fixed to a package (not shown) at the back surface of the first silicon substrate 11, that is, the surface of the first silicon substrate 11 at the opposite side to the oxide film 13 by adhesive agent or the like, and a circuit unit having a detection circuit 100 (see FIG. 3) described later is mounted in the package.

The circuit unit and each of the electrode pads 25a, 31a, 41a are electrically connected to thereto through a wire (not shown) which is formed of gold or aluminum by wire bonding or the like.

In the acceleration sensor S1 having the above basic construction, that is, the construction having the movable portion 20 and the fixed portions 30, 40, the applied acceleration can be detected according to the following basic operation.

In the basic construction, a first capacitor CS1 (capacitance CS1) is formed in the gaps between the first fixed electrodes 32 and the movable electrodes 24 and a second capacitor CS2 is formed in the gaps between the second fixed electrodes 42 and the movable electrodes 24.

Upon application of an acceleration, the overall movable portion 20 is integrally displaced in the displacement direction Y, and the capacitance of each of the capacitors CS1, CS2 is varied. The detection circuit 100 detects the acceleration thus applied on the basis of the variation in capacitance (CS1-CS2) between the capacitors CS1 and CS2.

FIG. 3 shows the detection circuit of the acceleration sensor S1. In the detection circuit 100, reference numeral 110 represents a switched capacitor circuit (SC circuit). The SC circuit 110 comprises a capacitor 111 having capacitance Cf, a switch 112 and a differentially amplifying circuit 113, and converts an input capacitance difference (CS1-CS2) to a voltage.

In the acceleration sensor S1 of this embodiment, for example, a carrier wave 1 of Vcc in amplitude is input from the fixed electrode pad 31a, and a carrier wave 2 whose phase is shifted from that of the carrier wave 1 by 180 degrees is input from the fixed electrode pad 41a to open/close the switch 112 of the SC circuit 110 at a predetermined timing. The applied acceleration is output as a voltage value V0 as shown in the following equation (1).
V0=(CS1−CS2)·Vcc/Cf (1)
Here, this embodiment has adjusting electrodes 50 for adjusting the spring constant of the spring portion 22.

As described above, the capacitance type dynamic quantity sensor detects the electrostatic capacitance between the movable electrodes and the fixed electrodes. As is apparent from the displacement of the movable portion described above, when a large acceleration is applied, the electrode intervals concerned are reduced, and the electrostatic capacitance is increased in inverse proportion to the intervals. Therefore, an area where the acceleration and the capacitance value are in linear relationship with each other is reduced.

Therefore, if the spring portion is constructed by a non-linearity spring in which the electrode interval is little when a large acceleration is applied, the relationship between the acceleration and the capacitance value would be nearer to linearity, and thus a broader acceleration range could be detected.

However, it is actually difficult to implement such a non-linearity spring, and thus such a non-linearity spring is apparently implemented by adjusting the spring constant of the spring portions 22. This is the effect achieved by the adjusting electrodes 50 of the acceleration sensor S1 according to this embodiment.

The basis construction, the basic operation, etc. of the acceleration sensor S1 according to this embodiment have been described above, and the unique feature of the adjusting electrodes 50 of this embodiment will be next described.

The adjusting electrodes 50 are disposed at such positions that the sticking between the pair of confronting portions of each spring portion 22, that is, between the beams 22a and 22b can be prevented.

Specifically, as shown in FIGS. 1, 2, the adjusting electrodes 50 are equipped at the outside of one (beam 22a) of the paired beams 22a, 22b and also at the outside of the other beam 22b. In the case of FIGS. 1, 2, a total of eight adjusting electrodes 50 are include. However, the number of adjusting electrodes 50 is not limited to eight, and may be more or less.

As shown in FIG. 2, each adjusting electrode 50 is supported on the oxide film 13, that is, the base portion 15. Furthermore, adjusting electrode pads 50a for wire bonding are formed of aluminum or the like and disposed at predetermined positions on the respective adjusting electrodes 50. Each adjusting electrode pad 50a is electrically connected to the circuit unit through a wire (not shown).

By applying voltages from the circuit unit to the adjusting electrodes 50, electrostatic force can be applied to the spring portions 22 so that the pair of beams 22a, 22b of each spring portion 22 are separated from each other.

Therefore, according to this embodiment, by applying the voltages to the adjusting electrodes 50, the motion of the spring portions 22 can be adjusted so that the confronting portions 22a, 22b of each spring portion are opened (i.e., separated from each other).

Further, it is simple to diversely change the polarity (positive/negative) of the voltage to be applied to each adjusting electrode 50. For example, when the detection sensitivity is enhanced, the spring constant of the spring portions 22 is reduced so that a large capacitance variation is achieved for even a small acceleration. At this time, the following operation is carried out to reduce the spring constant with respect to the downward movement of the spring portions 22 in the displacement direction Y in FIG. 1.

It is assumed that a positive potential is applied to the poise 21, the spring portions 22 and all the movable electrodes 24, that is, the movable portion 20. At this time, potential is applied to each adjusting electrode 50 so that the adjusting electrodes 50 located at the outside of the upper beam 22a of each spring portion 22 are set to a negative potential while the adjusting electrodes 50 located at the outside of the lower beam 22b of each spring portion 22 are set to a negative potential. With this voltage application, the movable portion 20 is more liable to move downwardly in the displacement direction Y.

Even when the confronting portions 22a, 22b of each spring portion 22 are brought into contact with each other, they can be separated from each other by the electrostatic force of the adjusting electrodes, so that the sticking of the spring portions 22 can be properly prevented. Specifically, the electrostatic force is generated so that each of the respective beams 22a, 22b of the spring portions 22 and each of the adjusting electrodes 50 at the outside thereof pull at each other.

The separation of the confronting portions 22a, 22b of the spring portions 22 from each other means that even when the movable electrode 24 and the fixed electrode 32, 42 facing the movable electrode 24 are brought into contact with each other, these electrodes kept in contact with each other can be separated from each other.

As described above, according to this embodiment, in the capacitance type dynamic quantity sensor having the adjusting electrodes, both the adjustment of the spring constant by the adjusting electrodes and the prevention of the sticking can be properly performed compatibly.

The acceleration sensor S1 of the embodiment shown in FIGS. 1 and 2 is a surface-processed type, however, the same construction as the above acceleration sensor S1 may be formed as a back-surface-processed type.

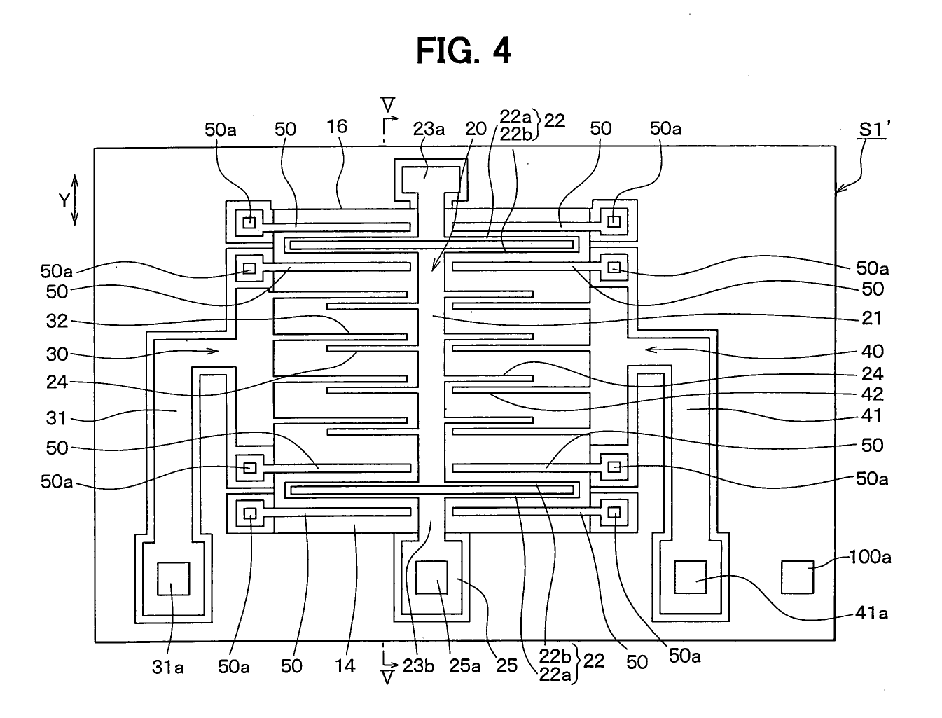

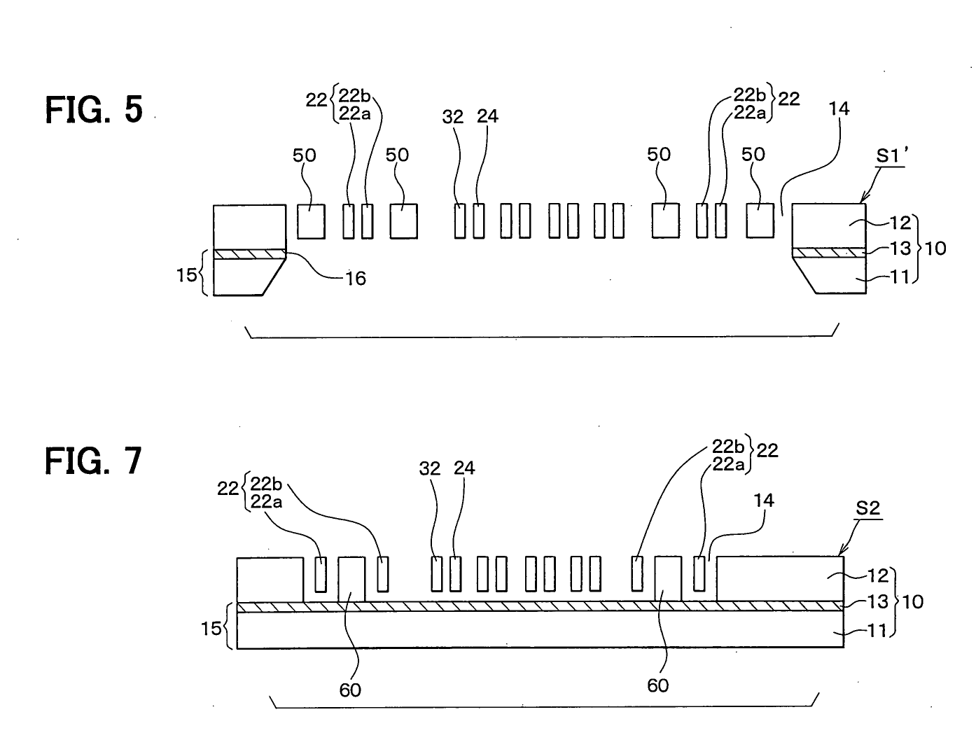

FIG. 4 is a diagram showing the planar construction of a back-surface-processed type acceleration sensor S1′, and FIG. 5 is a schematic cross-sectional view taken along a V-V line of FIG. 4 of the acceleration sensor S1′.

Like the above-described acceleration sensor S1, in the semiconductor substrate constituting the acceleration sensor S1′, the first silicon substrate 11 and the oxide film 13 constitute the base portion 15, and the beam structures 20, 30, 40, 50 are formed in the second silicon substrate 12.

Here, according to this modification, the oxide film 13 and the first silicon substrate 11 above which the movable portion 20, the comb-shaped portions of the fixed portions 30, 40 and the confronting portions of the adjusting electrodes 50 to the spring portions 22 are formed are removed, whereby an open portion 16 is formed there.

The sensor S1′ as described above is manufactured as follows. A mask having the shape corresponding to the beam structures is formed on the second silicon substrate 12 of the SOI substrate 10 by using the photolithography technique, and then trench etching is conducted by dry etching using gas of CF₄, SF₆ or the like to form grooves 14, whereby the beam structures 20 to 50 are formed in a lump.

Subsequently, the site at which the open portion 16 will be formed is etched from the back surface of the SOI substrate 10, that is, from the first silicon substrate (11) side by anisotropic etching using KOH or the like or etching using hydrofluoric acid, thereby forming the open portion 16.

As a result, the movable portion 20 is disposed so as to traverse on the open portion 16, and the poise portion 21, the spring portions 22 and the movable electrodes 24 are kept to face the open portion 16. Furthermore, with respect to the fixed portions 30, 40, the wire portions 31, 41 are fixedly mounted at the edge portion of the open portion 16, and the respective fixed electrodes 32 and 42 are kept to face the open portion 16.

Furthermore, the respective adjusting electrodes are cantilevered at the edge portion of the open portion 16, and the sites thereof which face the spring portions 22 are kept to face the open portion 16.

The acceleration sensor S1′ shown in FIGS. 4, 5 have the same operation and effect of the embodiment described above, and both the adjustment of the spring constant of the spring portions by the adjusting electrodes and the prevention of the sticking can be properly performed compatibly.

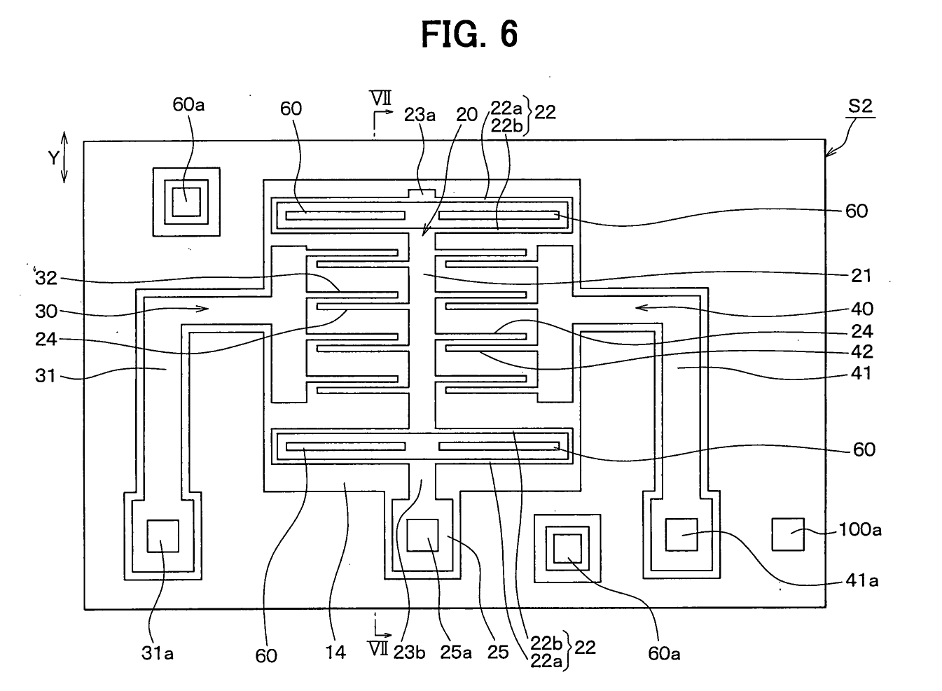

Referring to FIGS. 6-7, a second preferred embodiment of the differential capacitance type acceleration sensor S2 as a semiconductor dynamic quantity sensor will be discussed. The acceleration sensor S2 is also applicable to a vehicle acceleration sensor for controlling the operation of an air bag, ABS, VSC or the like, a gyro sensor, etc.

The basic construction, the manufacturing method, the basic operation, the implementation of the non-polarity spring by the adjusting electrodes, etc. for the acceleration sensor S2 are the same as described for the first embodiment. However, in this embodiment, the adjusting electrodes for adjusting the spring constant of the spring portions 22 are represented by reference numerals 60.

Next, the unique feature of the adjusting electrodes 60 according to this embodiment will be described.

According to this embodiment, the adjusting electrodes 60 are equipped at such positions that the sticking between the pair of confronting portions of each spring portion 22, that is, the beams 22a, 22b can be prevented.

Specifically, as shown in FIGS. 6, 7, the adjusting electrodes 60 are equipped so as to be interposed between the pair of confronting portions, that is, the two beams 22a and 22b of each spring portion 22. In the case of FIGS. 6, 7, every two adjusting electrodes 60 are equipped to each spring portion 22, that is, totally four adjusting electrodes 60 are equipped.

As shown in FIG. 7, each adjusting electrode 60 is supported on the oxide film 13, that is, the base portion 15. Furthermore, as shown in FIG. 6, the adjusting electrode pad 60a corresponding to the adjusting electrode 60 is formed of aluminum or the like and disposed at a predetermined position of the second silicon substrate 12.

In the case of FIG. 6, one adjusting electrode pad 60a is equipped in connection with the respective two adjusting electrodes 60 equipped in each of the upper spring portion and the lower spring portion 22.

Here, as not shown, the adjusting electrode 60 and the adjusting electrode pad 60a are electrically connected to each other through an inner-layer wire or the like which is equipped in the SOI substrate 10. Such an inner-layer wire may be formed by forming a wire layer composed of an impurity diffusion layer at a predetermined site of the first silicon substrate 11 by ion implantation, diffusion or the like or by forming a contact hole in the oxide film 13.

Each adjusting electrode pad 60a is electrically connected to the circuit unit by a wire (not shown), and voltages can be applied to the adjusting electrodes 60 by the circuit unit.

Accordingly, electrostatic force can be generated by applying the voltages to the adjusting electrodes 60 so that each adjusting electrode 60 and each spring portion 22 can pull each other or repel each other, and thus the spring constant of the spring portions 22 can be adjusted.

For example, when the detection sensitivity is enhanced, the spring constant of the spring portions 22 is reduced so that a large capacitance variation can be achieved for even a small acceleration. At this time, the following operation is carried out to reduce the spring constant with respect to the motion of the spring portions 22 in the downward direction in the displacement direction Y of FIG. 6.

It is assumed that a positive potential is applied to the poise portion 21, the spring portions 22 and the whole of the movable electrode 24, that is, the movable portion 20. At this time, potential is applied to each adjusting electrode 60 so that the adjusting electrodes 60 located in the spring portion 22 at the upper side of FIG. 6 are set to positive potential, and the adjusting electrodes 60 located in the spring portion 22 at the lower side of FIG. 6 are set to a negative potential. Under this potential application, the movable portion 20 is more liable to move downwardly in the displacement direction Y.

At this time, each adjusting electrode 60 may be disposed at the intermediate position between the spring portions 22a, 22b. However, in order to further increase the variation of the spring constant, the adjusting electrode 60 may be disposed so as to be nearer to the spring portion 22b which is near to the poise 21 because the adjusting electrode 60 is nearer to the spring portion 22b and thus the spring portion 22b is more intensely affected by the electrostatic force, so that the spring portion 22b is more liable to vary.

Furthermore, the adjusting electrodes 60 are interposed between the confronting portions 22a, 22b of the spring portion 22, the confronting portions 22a, 22b do not originally come into contact with each other. Therefore, the sticking of the spring portions 22 can be prevented.

The prevention of the contact between the confronting portions 22a, 22b of the spring portions 22 contributes to the prevention of the contact between the movable electrode 24 and the fixed electrode 32, 42 facing the movable electrode 24.

In this embodiment, when each of the beams 22a, 22b corresponding to the confronting portions of the spring portions 22 and each of the adjusting electrodes 60 are kept in contact with each other, the movable portion 20 and the adjusting electrodes 60 are set to the same potential and apply repelling electrostatic force to these portions so that each beam and each adjusting electrode 60 repels each other, whereby the beams 22a, 22b and the adjusting electrodes 60 can be easily separated from each other.

As described above, according to the capacitance type dynamic quantity sensor having the adjusting electrodes of this embodiment, both the adjustment of the spring constant of the sprint portions and the prevention of the sticking can be properly performed compatibly.

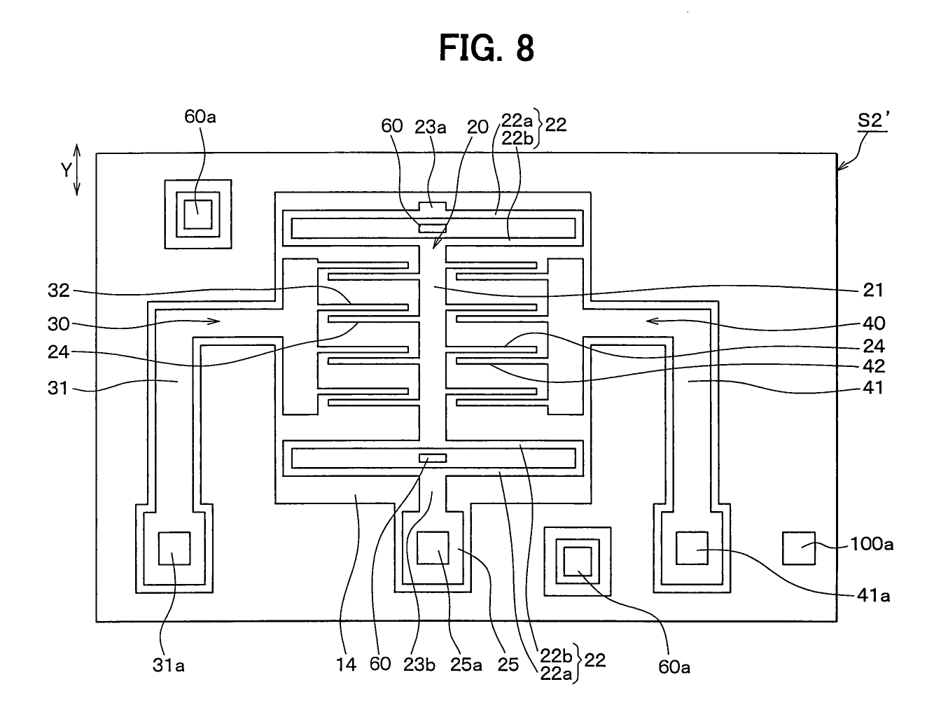

The construction that the adjusting electrodes 60 are interposed between the two beams 22a, 22b corresponding to the pair of confronting portions of the spring portion 22 may be modified like an acceleration sensor S2′. In the case of FIG. 8, one adjusting electrode 60 is equipped to each spring portion 22, that is, totally two adjusting electrodes 60 are equipped.

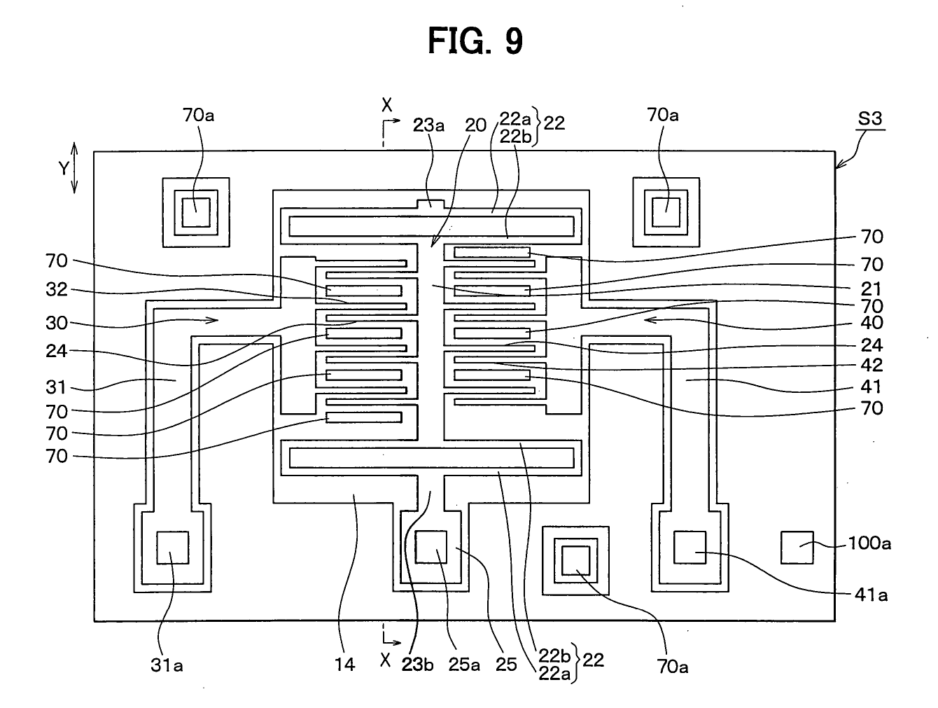

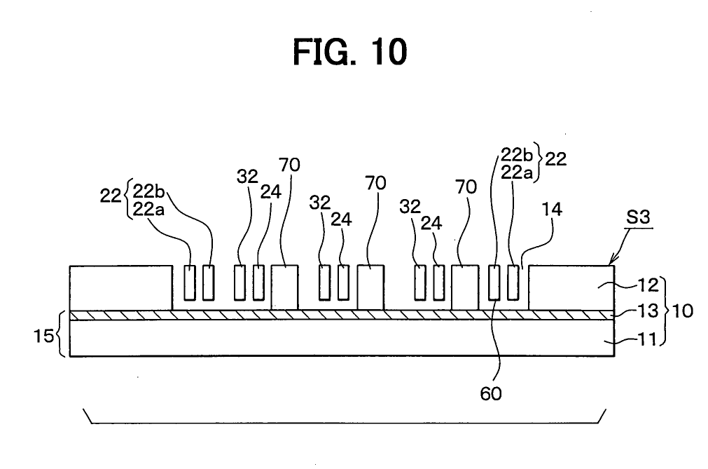

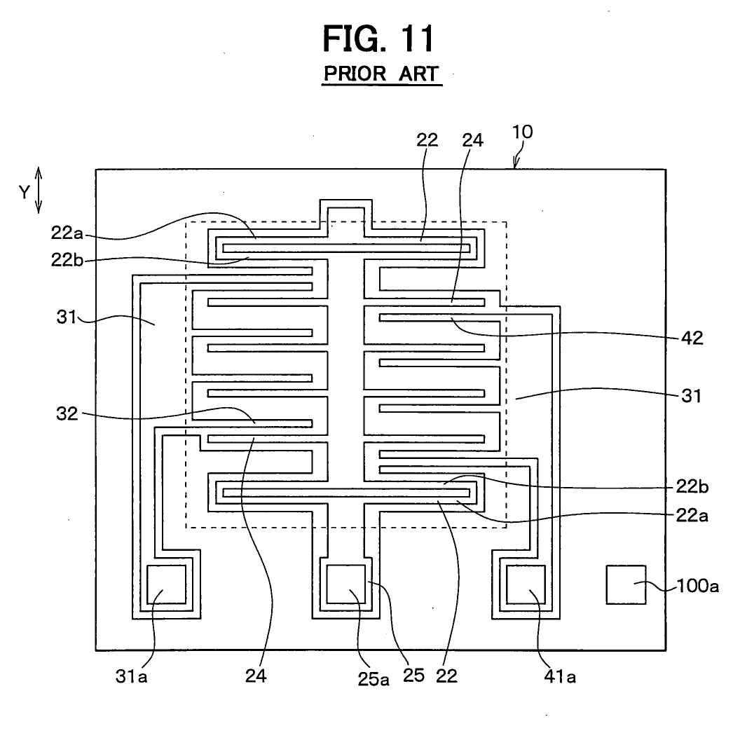

Referring to FIGS. 9-10, a differential capacitance type acceleration sensor S3 as a semiconductor dynamic quantity sensor according to a third preferred embodiment will be discussed. This acceleration sensor S3 is applicable to a vehicle acceleration sensor for controlling the operation of an air bag, ABS, VSC or the like, a gyro sensor or the like.

The sensor basic construction, the manufacturing method, the basic operation, the implementation of the non-linearity spring, etc. in the acceleration sensor S3 of this embodiment are the same as described for the first embodiment. However, in this embodiment, the adjusting electrodes for adjusting the spring constant of the spring portions are represented by reference numeral 70.

The adjusting electrodes 70 are equipped in the neighborhood of the movable electrodes 24 as the positions at which the sticking between the movable electrode 24 and the fixed electrode 32, 42 can be prevented. Specifically, as shown in FIGS. 9, 10, the adjusting electrodes 70 are disposed so as to be fitted in the gaps between the comb-shape teeth of the movable electrodes 24, and also face the opposite sites of the movable electrodes 24 to the fixed electrodes 32, 42. In the case of FIG. 9, every four adjusting electrodes 70 are equipped to each of the right and left sides of the poise portion 21, that is, totally eight adjusting electrodes 70 are equipped.

As shown in FIG. 10, each adjusting electrode 70 is supported on the oxide film 13, that is, the base portion 15. Furthermore, as shown in FIG. 9, adjusting electrode pads 70a for the adjusting electrodes 70 are formed of aluminum or the like and disposed at predetermined positions of the second silicon substrate 12.

In the case of FIG. 9, each adjusting electrode pad 70a is equipped in connection with each group of the four adjusting electrodes 70 disposed at the right or left side of the poise portion 21.

Here, as not shown, each of the adjusting electrodes 70 and each of the adjusting electrode pads 70a are electrically connected to each other by an internal-layer wire or the like which is equipped in the SOI substrate 10. Such an internal-layer wire can be formed by forming a wire layer composed of an impurity diffusion layer at a predetermined site of the first silicon substrate 11 by ion implantation, diffusion or the like or by forming a contact hole in the oxide film 13.

Each adjusting electrode pad 70a is electrically connected to the circuit unit described above by a wire (not shown) so that a voltage can be applied to each adjusting electrode 70 by the circuit unit.

According to this embodiment, the electrostatic force for separating the movable electrodes 24 from the fixed electrodes 32, 42 can be applied to the movable electrodes 24. That is, by applying the voltages to the adjusting electrodes 70, the electrostatic force can be acted so that the movable electrodes 24 are separated from the fixed electrodes 32, 42, and as a result the motion of the spring portions 22 can be adjusted.

Further, the polarity (positive/negative sign) of the voltage to be applied to each adjusting electrode 70 can be easily freely changed. For example, when the detection sensitivity is enhanced, the spring constant of the spring portions 22 is reduced so that a large capacitance variation can be achieved for even a small acceleration. At this time, the following operation is carried out to reduce the spring constant with respect to the downward motion of the spring portion 22 in the displacement direction of FIG. 9.

It is assumed that a positive potential is applied to the poise portion 21, the spring portions 22 and the whole movable electrodes 24, that is, the movable portion 20. At this time, potential is applied to each adjusting electrode 70 so that the adjusting electrodes 70 located at the left side of the poise portion 21 are set to a negative potential, and the adjusting electrodes 70 located at the right side of the poise portion 21 are set to positive potential. Under this potential application, the movable portion 20 is more liable to move downwardly in the displacement direction.

Even when each of the movable electrodes 24 and each of the fixed electrodes 32, 42 come into contact with each other, both the electrodes can be separated from each other by the electrostatic force of the adjusting electrodes 70, so that the sticking between each of the movable electrodes 24 and each of the fixed electrodes 32, 42 can be properly prevented.

Furthermore, the separation between each of the movable electrodes 24 and each of the fixed electrodes 32, 42 means that even when the confronting portions 22a, 22b of each spring portion 22 are kept in contact with each other, both the confronting portions 22a, 22b kept in contact with each other can be separated from each other.

As described above, according to the capacitance type dynamic quantity sensor having the adjusting electrodes of this embodiment, the adjustment of the spring constant of the spring portions by the adjusting electrodes and the prevention of the sticking can be properly performed compatibly.

The shape of the movable and fixed electrodes of the acceleration sensor is not limited to the comb shape as described above. Rather, each of the movable electrodes and each of the fixed electrodes may be generally disposed so as to face each other at such an interval that the capacitance detection can be sufficiently performed.

Furthermore, in the above embodiment, the spring portion is designed in a rectangular shape in which the two parallel beams 22a, 22b as the pair of confronting portions facing along the displacement direction of the spring portion are linked to each other at both the ends thereof, however, the shape of the spring portion of present invention is not limited to the rectangular shape. For example, the shape of the spring may be a spiral shape, a fold-back (or meandering) shape or the like.

Furthermore, the present invention is applicable to not only the acceleration sensor, but also an angular velocity sensor, etc.

The description of the invention is merely exemplary in nature and, thus, variations that do not depart from the gist of the invention are intended to be within the scope of the invention. Such variations are not to be regarded as a departure from the spirit and scope of the invention.

1. A semiconductor dynamic quantity sensor comprising:
a spring portion joined to a base portion and elastically displaceable in a predetermined direction in accordance with an applied dynamic quantity;
a movable electrode which is joined to the spring portion and displaceable in the predetermined direction together with the spring portion;
a fixed electrode which is fixed to the base portion and disposed so as to face the movable electrode; and
adjusting electrodes for adjusting a spring constant of the spring portion,
wherein the applied dynamic quantity is detected on the basis of variation of an interval between the movable electrode and the fixed electrode when the movable electrode is displaced in the predetermined direction in accordance with the applied dynamic quantity,
wherein the spring portion has a pair of confronting portions facing each other along the predetermined direction and are elastically deformed so that the interval between the confronting portions is varied, and the adjusting electrodes are equipped at positions for preventing sticking between the pair of confronting portions of the spring portion or sticking between the movable electrode and the fixed electrodes.

2. The semiconductor dynamic quantity sensor according to claim 1, wherein the positions for preventing the sticking between the pair of confronting portions comprises respectively equipping the adjusting electrodes outside of one of the pair of confronting portions and outside of the other confronting portion, so that electrostatic force for separating the pair of confronting portions from each other can be applied by the adjusting electrodes

3. The semiconductor dynamic quantity sensor according to claim 1, wherein the positions for preventing the sticking between the pair of confronting portions comprises interposing the adjusting electrodes between the pair of confronting portions.

4. The semiconductor dynamic quantity sensor according to claim 1, wherein the positions for preventing the sticking between the pair of confronting portions comprises equipping the adjusting electrodes in the neighborhood of the movable electrode, and the electrostatic force can be applied to the movable electrode by the adjusting electrodes so that the movable electrode and the fixed electrodes are separated from each other.

5. The semiconductor dynamic quantity sensor according to claim 4, wherein the movable electrode is designed in a comb-shape having teeth extending in a direction perpendicular to the predetermined direction, and the fixed electrode is designed in a comb-shape having teeth and disposed to face the movable electrode so that each of the teeth of the comb-shape of the fixed electrode is fitted in a gap between respective teeth of the comb-shape of the movable electrode

6. A semiconductor dynamic quantity sensor comprising:
a base portion;
a spring portion joined to the base portion and elastically displaceable in a predetermined direction in accordance with an applied dynamic quantity, the spring portion having a pair of confronting portions which face each other along the predetermined direction and are elastically deformed so that the interval between the confronting portions is varied;
a movable electrode joined to the spring portion and displaceable in the predetermined direction together with the spring portion;
a fixed electrode fixed to the base portion and disposed to face the movable electrode; and
a sticking control electrode disposed to face one of the pair of confronting portions of the spring portion and that can apply electrostatic force to the spring portion so that the pair of confronting portions are separated from each other.
